(19) United States
(12) Patent Application Publication
(10) Pub. No.: US 2025/0151360 A1
(43) Pub. Date: May 8, 2025

(54) HIGH ELECTRON MOBILITY TRANSISTOR DEVICE

(71) Applicant: XIAMEN SAN'AN INTEGRATED CIRCUIT CO., LTD., Xiamen (CN)

(72) Inventors: Wenjie SONG, Xiamen (CN); Jiebin ZHONG, Xiamen (CN); Shenghou LIU, Xiamen (CN)

(21) Appl. No.: 18/796,914

(22) Filed: Aug. 7, 2024

Related U.S. Application Data
(63) Continuation-in-part of application No. PCT/CN2023/129605, filed on Nov. 3, 2023.

(51) Int. Cl. H01L 29/40; H01L 21/033; H01L 21/285; H01L 21/311; H01L 23/31; H01L 29/423; H01L 29/66; H01L 29/778

(52) U.S. Cl. CPC H10D 64/111; H01L 21/0337; H01L 21/31122; H01L 23/3171; H10D 30/015; H10D 64/518; H01L 21/28506; H10D 30/475

(57) ABSTRACT

An HEMT device includes a semiconductor epitaxial layer, a source electrode, a drain electrode, a gate electrode, a field plate structure, a first passivation layer, and a second passivation layer. The gate electrode includes a gate foot and a gate cap. The field plate structure includes a first portion, a second portion, a third portion, an extension portion. The second passivation layer has a first groove. The first groove has a first sidewall and a second sidewall. The first sidewall forms a first inclining angle with an imaginary line parallel to a gate length direction. The second sidewall and the imaginary line form a second inclining angle. Both of the first inclining angle and the second inclining angle are formed outside the first groove, and the first inclining angle is greater than the second inclining angle. A method for manufacturing the HEMT device is also provided.

### CROSS-REFERENCE TO RELATED APPLICATION

This application is a continuation-in-part (CIP) of International Application No. PCT/CN2023/129605, filed on Nov. 3, 2023, the entire disclosure of which is incorporated by reference herein.

### FIELD

The disclosure relates to a semiconductor device, and more particularly to a high electron mobility transistor device and a method of manufacturing the same.

### BACKGROUND

High electron mobility transistors (HEMT) have the advantages of being capable of operating at high frequency, high voltage, high temperature, etc. The third generation semiconductor material GaN has received much attention in research for having a large bandwidth (3.4 eV), high electron saturation velocity (2×107 cm/s), high breakdown electric field (˜3×1010 V/cm), high thermal conductivity, corrosion and radiation resistance, etc., and has a prospect of broad applications. In particular, a high electron mobility transistor having a heterojunction structure of AlGaN/GaN is capable of operating at high frequency and high temperature, and has a high power density, so it is used in high power microwave devices or devices that are required to operate at high temperature. Much research has been focused on the AlGaN/GaN high electron mobility transistor.

To ensure that the GaN HEMT device can maximize its superior properties of large bandwidth, a proper design of a field plate is essential. Currently, the field plate is designed to cover a gate electrode or a part of the gate electrode in a flat manner, and to extend towards a drain electrode for a distance. However, such conventional design does not distribute an electric field evenly when the GaN HEMT device operates under high power, and therefore may fail to meet the requirements of high frequency, high power, high power density, etc. Therefore, re-designing and optimizing the profile and structural configuration of the field plate becomes a technical issue to be resolved.

### SUMMARY

Therefore, an object of the disclosure is to provide a high electron mobility transistor (HEMT) device that can alleviate at least one of the drawbacks of the prior art.

According to a first aspect of the disclosure, the HEMT device includes a semiconductor epitaxial layer, a source electrode, a drain electrode, and a gate electrode.

The source electrode, the drain electrode, and the gate electrode are disposed on the semiconductor epitaxial layer. The source electrode and the drain electrode are disposed opposite to each other. The gate electrode is disposed between the source electrode and the drain electrode, and the gate electrode includes a gate foot and a gate cap.

The HEMT device further includes a field plate structure, a first passivation layer, and a second passivation layer.

The field plate structure includes a first portion, a second portion, and a third portion that extends downwardly from the first portion to the second portion. The first portion is disposed on the gate cap of the gate electrode. The second portion is disposed between the gate electrode and the drain electrode, and extends on the second passivation layer in a gate length direction. The first passivation layer is disposed between the gate cap of the gate electrode and the semiconductor epitaxial layer. The second passivation layer is disposed between the field plate structure and the gate electrode, and has a first groove. The second passivation layer covers the gate electrode at a gated region, and covers the first passivation layer at a non-gated region. The field plate structure further includes an extension portion that is disposed in the first groove of the second passivation layer between the drain electrode and the gate electrode. The first groove has a first sidewall that is closer to the gate electrode than the drain electrode, and a second sidewall opposite to the first sidewall in the gate length direction. The first sidewall forms a first inclining angle with an imaginary line parallel to the gate length direction. The second sidewall and the imaginary line parallel to the gate length direction form a second inclining angle. Both of the first inclining angle and the second inclining angles are formed outside the first groove, and the first inclining angle is greater than the second inclining angle.

According to a second aspect of the disclosure, a method for manufacturing the HEMT device includes steps of:
forming a semiconductor epitaxial layer;
forming a source electrode and a drain electrode that are opposite to each other on the semiconductor epitaxial layer;
forming a first passivation layer;
forming a gate electrode;
forming a second passivation layer on the first passivation layer and the gate electrode;
forming and photolithographically etching a first photoresist layer to form a first window that exposes the second passivation layer, followed by a photoresist reflow process under a temperature ranging from 80° C. to 200° C. for a period of 2 minutes to 60 minutes, the first window being located between the gate electrode and the drain electrode and being closer to the gate electrode along a gate length direction, a bottom of the first photoresist layer that is in contact with the second passivation layer having a first length in the gate length direction from an end of the gate electrode to a bottom of a first window wall of the first window closer to the gate electrode than the drain electrode, the bottom of the first photoresist layer that is in contact with the second passivation layer further having a second length in the gate length direction from the drain electrode to a bottom of a second window wall of the first window closer to the drain electrode than the gate electrode, the second length being greater than the first length, the first window wall forming a first angle with the second passivation layer proximate to the gate electrode, the second window wall forming a second angle opposite to the first angle and distal from the gate electrode, the second angle being smaller than the first angle, both of the first angle and the second angle being formed outside the first window;
etching the second passivation layer exposed from the first photoresist layer between the gate electrode and the drain electrode to form a first groove;
removing the first photoresist layer, and forming and photolithographically etching a second photoresist layer to form a second window; and
depositing a field plate structure in the second window.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIGS. 1 to 7, 9, 10, and 12 are schematic views illustrating a method of manufacturing a first embodiment of a nitride-based HEMT device according to the present disclosure.

FIG. 8 is a partially enlarged schematic view of region A in FIG. 7.

FIG. 11 is a partially enlarged schematic view of region B in FIG. 10.

FIG. 13 is a partially enlarged schematic view of region C in FIG. 12.

FIG. 14 is a schematic view illustrating a two-layer second passivation layer for a second embodiment of the nitride-based HEMT device of the present disclosure.

FIG. 15 is a schematic view illustrating the second embodiment of the nitride-based HEMT device according to the present disclosure.

FIG. 16 is a schematic view illustrating a third embodiment of the nitride-based HEMT device according to the present disclosure.

FIG. 17 is a schematic view illustrating a fourth embodiment of the nitride-based HEMT device according to the present disclosure.

FIG. 18 is a partially enlarged schematic view of a first groove in FIG. 17.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

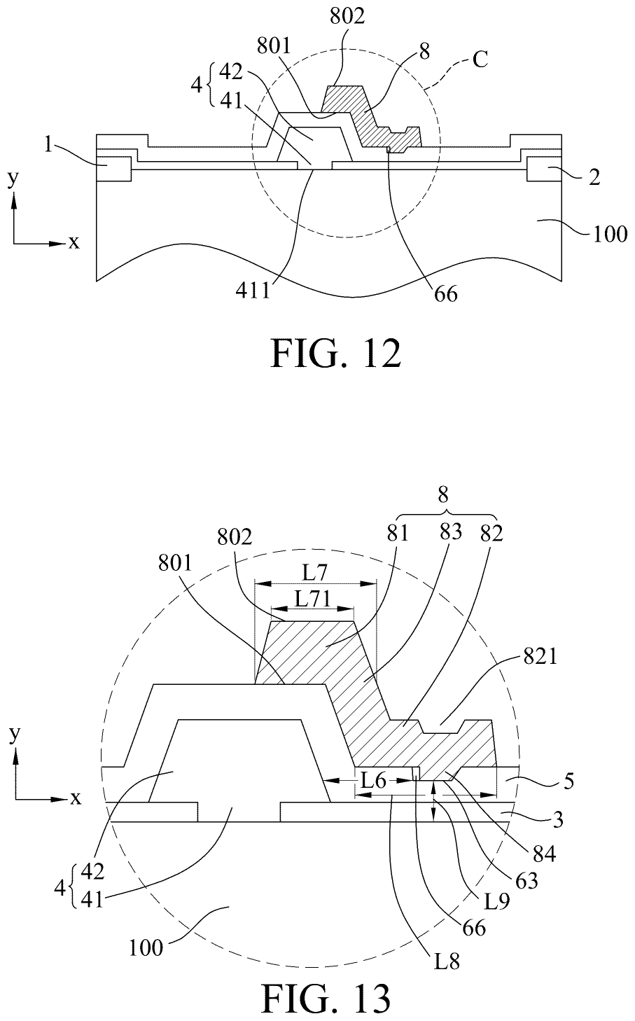

Referring to FIGS. 12 and 13, a first embodiment of a nitride-based HEMT device according to the disclosure includes a semiconductor epitaxial layer 100 which includes a substrate, a channel layer, and a barrier layer sequentially disposed in a bottom-top direction (y), a source electrode 1, a drain electrode 2, and a gate electrode 4 disposed on the semiconductor epitaxial layer 100. The source electrode 1 and the drain electrode 2 are disposed opposite to each other. The gate electrode 4 has a T shape, is disposed between the source electrode 1 and the drain electrode 2, and includes a gate foot 41 and a gate cap 42. In the bottom-top direction (y), a thickness of the gate cap 42 ranges from 0.1 μm to 1 μm, and a thickness of the gate foot 41 ranges from 0.05 μm to 0.5 μm. In a gate length direction (x, i.e., from the source electrode 1 to the drain electrode 2), a dimension of the gate foot 41 ranges from 0.1 μm to 1 μm. The gate length direction (x) and the bottom-top direction (y) are perpendicular to each other.

The HEMT device further includes a field plate structure 8, a first passivation layer 3, and a second passivation layer 5. The first passivation layer 3 is disposed between the gate cap 42 of the gate electrode 4 and the semiconductor epitaxial layer 100. The second passivation layer 5 is disposed between the field plate structure 8 and the gate electrode 4, and has a first groove 63.

The second passivation layer 5 covers the gate electrode 4 at a gated region, and covers the first passivation layer 3 at a non-gated region.

The field plate structure 8 includes a first portion 81, a second portion 82, and a third portion 83 that extends downwardly from the first portion 81 to the second portion 82. The first portion 81 is disposed on the gate cap 42 of the gate electrode 4. The second portion 82 is disposed between the gate electrode 4 and the drain electrode 2, and extends on the second passivation layer 5 in the gate length direction (x). The source electrode 1, the gate electrode 4, the drain electrode 2, and the field plate structure 8 are spaced apart by the first passivation layer 3 and the second passivation layer 5. The field plate structure 8 further includes an extension portion 84 that is disposed in the first groove 63 of the second passivation layer 5 between the drain electrode 2 and the gate electrode 4. In the gate length direction (x), a dimension of the extension portion 84 ranges from 0.3 μm to 1.5 μm. The extension portion 84 is formed by a sinking region of the second portion 82 that sinks downwardly. This sinking region creates a second recess 821 (see FIG. 13) above the extension portion 84. In this way, a distance between the field plate structure 8 and a conductive channel is shortened, a metallic area of the field plate structure 8 between the gate electrode 4 and the drain electrode 2 is increased, and an undesired voltage modulation of electric charges in the gated region by the drain electrode 2 is moderated. That is to say, parasitic capacitance (Cgd) is reduced, and gain performance of a radio frequency (RF) device is improved. At the same time, an electric field of the semiconductor epitaxial layer 100 may be modulated more uniformly. The extension portion 84 may produce additional parasitic capacitance (Cgs2). To reduce the Cgs2, a cavity 66 is formed in the first groove 63 adjacent a first sidewall 511 of the first groove 63 that is closer to the gate electrode 4 than the drain electrode 2. By virtue of the cavity 66 having a low dielectric constant compared to a high dielectric constant of the structure filled in the first groove 63, the cavity 66 may reduce parasitic capacitance (Cgs1) formed between a field plate metal at the left of the first groove 63 and the gate electrode 4, thereby improving the gain performance of the RF device and the RF performance. The Cgs2 is the additional parasitic capacitance when the cavity 66 does not exist, and therefore is greater in value compared to the Cgs1. The Cgs1 is the parasitic capacitance when the cavity 66 exist, and therefore is smaller in value compared to the Cgs2. The cavity 66 may enhance the effect of modulating an electric field of the field plate structure 8 and may also prevent an increase in the parasitic capacitance to a greater extent, thereby achieving a balance between an electric field modulation and a parasitic capacitance reduction. It should be noted that, because the cavity 66 is located at a junction between the second portion 82 and the extension portion 84 of the field plate structure 8, the cavity 66 is completely surrounded by metal and dielectric materials, is protected by a thick layer of the dielectric materials on top, and is smaller in volume compared to the field plate structure 8 and the first and second passivation layers 3, 5, so it is unlikely that moisture can get into the cavity 66.

According to a simulation, in the gate length direction (x), when a sidewall angle of the extension portion 84 closer to the gate electrode 4 is greater than 70° and smaller than 90°, for example, in a range from 80° to 85°, the cavity 66 may be ensured to have a greater volume, thereby reducing the parasitic capacitance.

According to a simulation, in the gate length direction (x), an electric field strength at a bottom portion of the extension portion 84 closer to the gate electrode 4 is smaller than an electric field strength at a bottom portion of the extension portion 84 closer to the drain electrode 2. To prevent the electric field strength from being concentrated at the bottom portion of the extension portion 84 closer to the drain electrode 2, which is a peak electric field region, a sidewall angle of the extension portion 84 closer to the drain electrode 2 is greater than 90° and smaller than 150°, so as to avoid the electric field strength from being concentrated thereat. By virtue of the field plate structure 8 sinking downwardly, an electric field distribution of the RF device is further optimized, voltage resistance of the RF device is increased, and performance of the RF device under electrical stress is improved.

In the gate length direction (x), a dimension (L7) of the first portion 81 ranges from 0.2 μm to 3 μm. A dimension (L71) of a top portion of the first portion 81 ranges from 0.1 μm to 1.3 μm. A portion of the field plate structure 8 away from the drain electrode 2 (i.e., the first portion 81) may be extended and kept away from the peak electric field region, thereby reducing voltage leak when the RF device is off.

In the gate length direction (x), a dimension (L8) of the second portion 82 ranges from 0.2 μm to 3 ηm.

The dimension (L8) of the second portion 82 is greater than the dimension (L7) of the first portion 81 (i.e., L8>L7). The greater dimension (L8) of the second portion 82 may reduce an average strength of the peak electric field region, thereby improving uniformness of the peak electric field region. The smaller dimension (L7) of the first portion 81 may reduce an area of the field plate structure 8 that overlaps the gate electrode 4 and reduce the parasitic capacitance (Cgs), thereby improving the performance of the RF device.

In the gate length direction (x), a dimension of the cavity 66 ranges from 0.01 μm to 0.1 μm. A minimum distance (L6) between a bottom surface of the cavity 66 and the gate electrode 4 ranges from 0.2 μm to 2 μm.

In the gate length direction (x), a minimum distance between the extension portion 84 and the gate electrode 4 ranges from 0.05 μm to 1 μm, and the minimum distance between the extension portion 84 and the gate electrode 4 is directly proportional to a thickness of the second passivation layer 5.

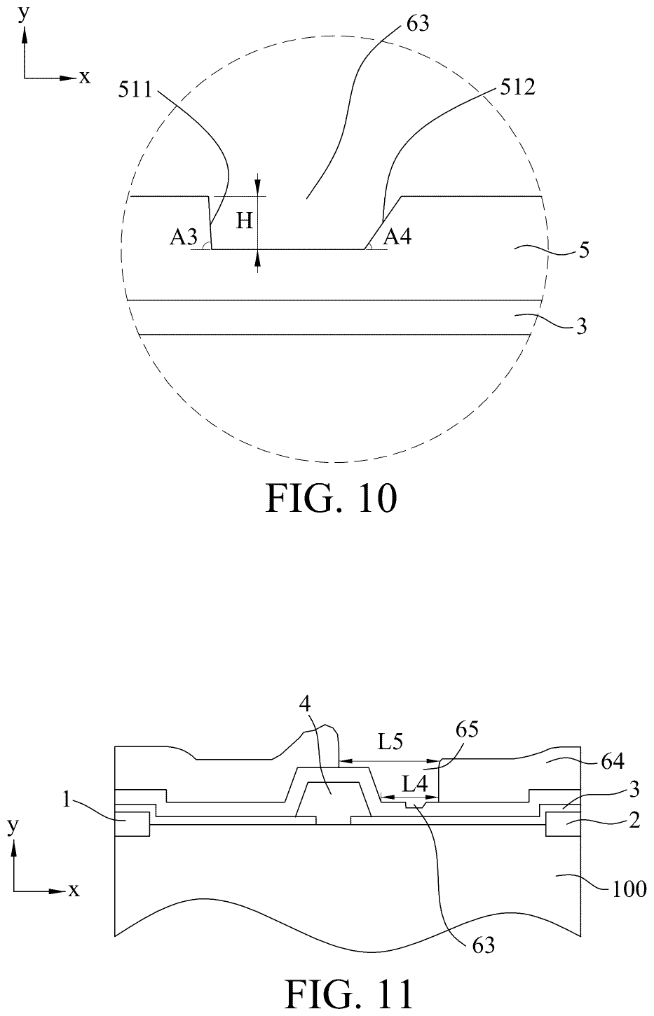

Referring to FIG. 10, in the gate length direction (x), the first groove 63 further has a second sidewall 512 opposite to the first sidewall 511 (i.e., away from the gate electrode 4). The first sidewall 511 forms a first inclining angle (A3) with an imaginary line parallel to the gate length direction (x), and the second sidewall 512 and the imaginary line parallel to the gate length direction (x) form a second inclining angle (A4). Both of the first inclining angle (A3) and the second inclining angle (A4) are formed outside the first groove 63, and the first inclining angle (A3) is greater than the second inclining angle (A4). Therefore, formation of the cavity 66 at the first sidewall 511 is facilitated in subsequent steps of forming the field plate structure 8 by deposition. The second sidewall 512 may enable the field plate structure 8 to cover the second passivation layer 5 more effectively. A distance between a bottom surface of the first groove 63 and a top surface of the semiconductor epitaxial layer 100 ranges from 100 nm to 500 nm, thereby further reducing the parasitic capacitance (Cgd), and improving the performance of the RF device.

The greater the first inclining angle (A3) is, the easier it is to form the cavity 66 and the greater the cavity 66 is. In some embodiments, the first inclining angle (A3) ranges from 80° to 90°. When the first inclining angle (A3) is smaller than 80°, it is more difficult to form the cavity 66.

The greater the second inclining angle (A4) is, the steeper the slope of the second sidewall 512 is, which is not beneficial to the forming of the field plate structure 8. The smaller the second inclining angle (A4) is, the closer the extension portion 84 of the field plate structure 8 is to the drain electrode 2, and the closer the extension portion 84 of the field plate structure 8 is to the semiconductor epitaxial layer 100. This may result in a stronger electric field at the extension portion 84 and is not conducive to the performance of the RF device. In some embodiments, the second inclining angle (A4) ranges from 30° to 70°, which may effectively ensure that the extension portion 84 covers the second passivation layer 5, and that an obtuse angle is easily formed at an end of the extension portion 84 closer to the drain electrode 2 so as to weaken the peak electric field region closer to the drain electrode 2, thereby avoiding the electric field strength from being concentrated thereat and improving the voltage resistance of the RF device.

Furthermore, a difference between the first inclining angle (A3) and the second inclining angle (A4) ranges from 20° to 50°.

A thickness of the first passivation layer 3 ranges from 50 nm to 500 nm, and the thickness of the second passivation layer 5 ranges from 100 nm to 2000 nm.

A depth of the first groove 63 depends on the thickness of each of the first passivation layer 3 and the second passivation layer 5, as well as the distance between the bottom surface of the first groove 63 and the top surface of the semiconductor epitaxial layer 100. In this embodiment, the depth of the first groove 63 ranges from 50 nm to 2000 nm.

The second passivation layer 5 is a single layered structure. The first passivation layer 3 is a multilayered structure. In some embodiments, the first passivation layer 3 has two layers, which include a first dielectric layer that has a thickness ranging from 1 nm to 10 nm, and a second dielectric layer that has a thickness ranging from 10 nm to 490 nm. The first dielectric layer is made of a silicon nitride material by plasma-enhanced chemical vapor deposition (PECVD), and the second dielectric layer is made of a silicon nitride material by low pressure chemical vapor deposition (LPCVD).

It should be noted that the first passivation layer 5 may be a single layered structure.

The second portion 82 further includes a second groove 821 (see FIG. 13) having a shape of an inverted trapezoid.

Furthermore, the first portion 81 includes a bottom surface 801 (see FIG. 12) contacting the second passivation layer 5 and a top surface 802 (see FIG. 12) opposite to the bottom surface 801. Each of the bottom surface 801 and the top surface 802 has an end portion proximate to the source electrode 1, and a projection of the end portion of the bottom surface 801 on the semiconductor epitaxial layer 100 is closer to the source electrode 1 than a projection of the end portion of the top surface 802 on the semiconductor epitaxial layer 100. The gate foot 41 has a gate foot bottom surface 411 which is in contact with the semiconductor epitaxial layer 100. A projection of the bottom surface 801 on the semiconductor epitaxial layer 100 and a projection of the top surface 802 on the semiconductor epitaxial layer 100 overlap a projection of the gate foot bottom surface 411 of the gate foot 41 on the semiconductor epitaxial layer 100.

It should be noted that in this embodiment, the first portion 81, the second portion 82, the third portion 83, and the extension portion 84 of the field plate structure 8 are formed by the same deposition step. The field plate structure 8 may have a single layered structure or a multilayered structure, with its main material being gold, but may also include metallic materials that prevent gold diffusion such as platinum, nickel, molybdenum, palladium, tungsten, and vanadium, and metallic materials that enhance adhesion between layers such as metallic titanium, nickel, aluminum, chromium, and vanadium. The field plate structure 8 may be formed by sequentially depositing a metallic material that enhances adhesion, a metallic material that prevents gold diffusion, gold, and a protective material.

A method for manufacturing the HEMT device includes the following steps.

First, the semiconductor epitaxial layer 100 having a heterojunction structure is formed by sequentially forming the channel layer and the barrier layer on the substrate. The substrate may be a SiC substrate, a Si substrate, a sapphire substrate, etc., or any other substrate made of a GaN material that is appropriate for epitaxial growth and known to a person skilled in the art.

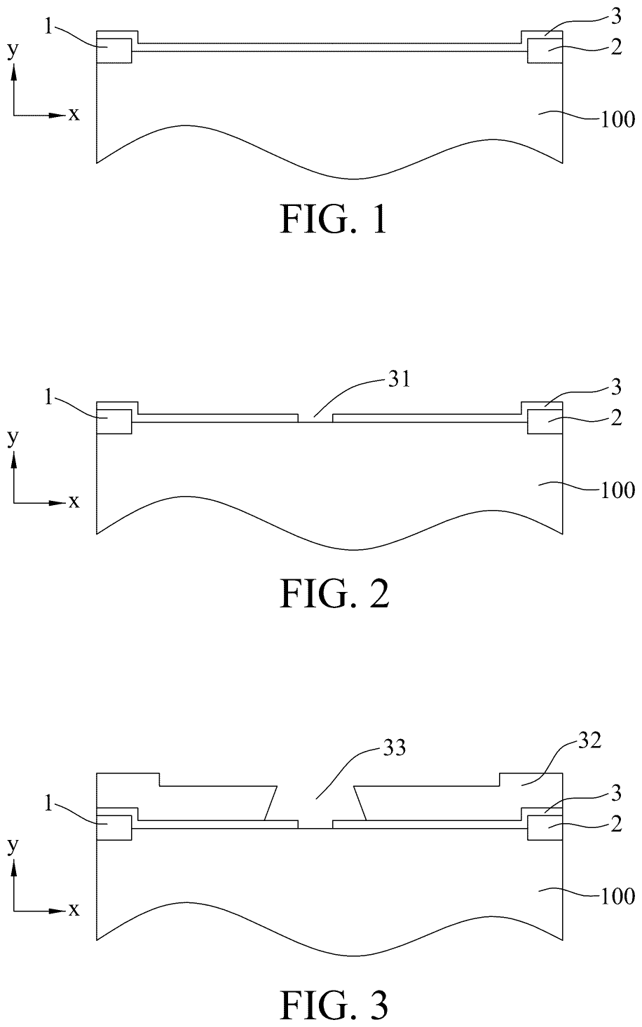

Next, the source electrode 1 and the drain electrode 2 that are opposite to each other are formed on the semiconductor epitaxial layer 100, as shown in FIG. 1.

Then, referring to FIG. 2, the first passivation layer 3 is formed and photolithographically etched to form a window 31 between the source electrode 1 and the drain electrode 2, thereby exposing the semiconductor epitaxial layer 100. The first passivation layer 3 may include one or a plurality of dielectric layers, and may be made of SiN, SiO₂, AlN, Al₂O₃, etc.

Referring to FIG. 3, a photoresist layer 32 is formed and photolithographically etched to form a window 33. In the gate length direction (x), a dimension of the window 33 is greater than a dimension of the window 31.

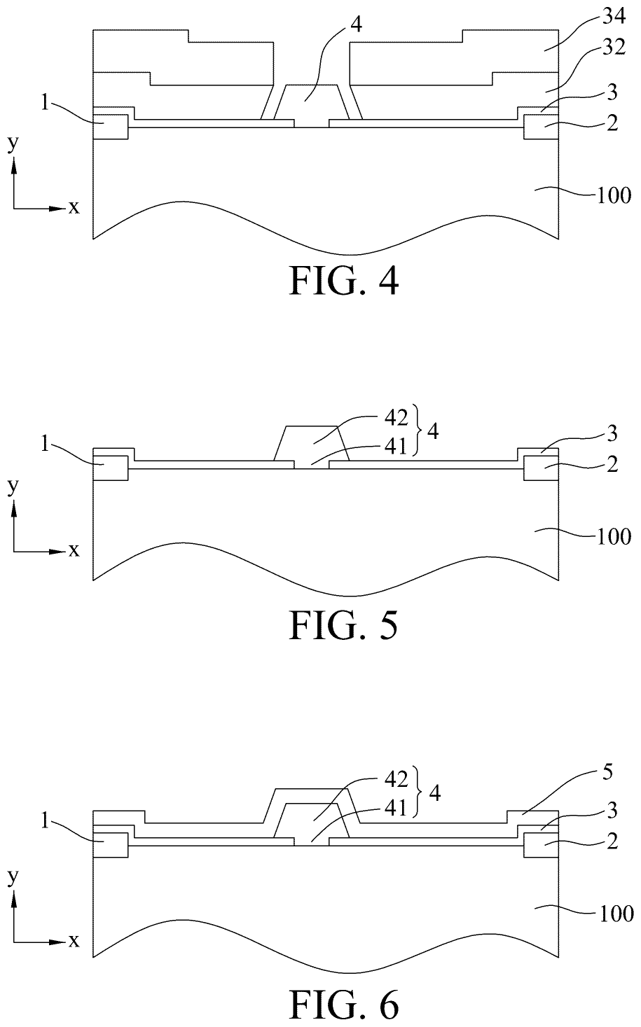

Referring to FIG. 4, a gate metal layer 34 is formed by electron beam physical vapor deposition in the windows 31, 33 and on the photoresist layer 32. Since electron beam physical vapor deposition has a collimation film coverage property, combining with a trapezoidal shape of the window 33, the gate metal layer 34 is deposited in the bottom-top direction (y) so that the gate metal layer 34 formed in the windows 31, 33 is spaced from and does not adhere to the photoresist layer 32.

Referring to FIG. 5, the photoresist layer 32 and the gate metal layer 34 on the photoresist layer 32 are removed so as to form the gate electrode 4.

Referring to FIG. 6, the second passivation layer 5 is formed on the gate electrode 4 and the first passivation layer 3. The thickness of the second passivation layer 5 is greater than the thickness of the first passivation layer 3.

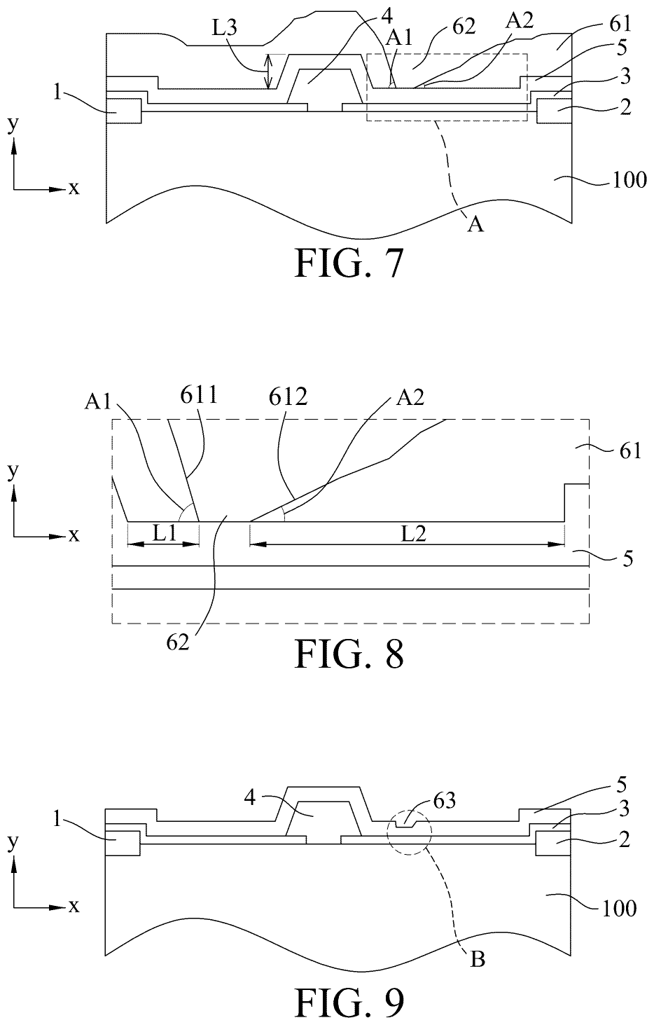

Referring to FIGS. 7 and 8, a first photoresist layer 61 is formed and photolithographically etched to form a first window 62 that exposes the second passivation layer 5, followed by a photoresist reflow process under a temperature ranging from 80° C. to 200° C. for a period of 2 minutes to 60 minutes. The first window 62 is located between the gate electrode 4 and the drain electrode 2, and is closer to the gate electrode 4 in a gate length direction (x), as shown in FIGS. 7 and 8. A bottom of the first photoresist layer 61 that is in contact with a surface of the second passivation layer 5 has a first length (L1) in the gate length direction (x) from a point on the surface of the second passivation layer 5 closer to the gate electrode 4 at a drain side to a bottom of a first window wall 611 of the first window 62 closer to the gate electrode 4 than the drain electrode 2. The bottom of the first photoresist layer 61 that is in contact with the second passivation layer 5 further has a second length (L2) in the gate length direction (x) from the drain electrode 2 to a bottom of a first window wall 612 of the first window 62 closer to the drain electrode 2 than the gate electrode 4. The second length (L2) is greater than the first length (L1).

A thickness of the first photoresist layer 61 ranges from 0.1 μm to 4 μm and is subjected to baking after photolithographic etching. The first length (L1) ranges from 0.2 μm to 2 μm. A top surface of the second passivation layer 5 has a height difference (L3) between an area where the gate electrode 4 exists (i.e., the gated region) and an area where the gate electrode 4 does not exist (i.e., the non-gated region). The height difference (L3) ranges from 0.1 μm to 1 μm. The height difference (L3) causes poor mobility of a photoresist material at one side of the first window 62 proximate to the gate electrode 4 during reflow. A baking temperature may not be too low. When the baking temperature is lower than 110° C., an effective angle of the first photoresist layer 61 may not be formed. Mobility of the photoresist material at another side of the first window 62 distal from the gate electrode 4 is better, and the photoresist material thereat forms a better angle after being baked. The first window wall 611 forms a first angle (A1) with the second passivation layer 5 proximate to the gate electrode 4, and the second window wall 612 forms a second angle (A2) opposite to the first angle (A1) and distal from the gate electrode 4. The second angle (A2) is smaller than the first angle (A1), and both of the first angle (A1) and the second angle (A2) are formed outside the first window 62. The first angle (A1) ranges from 80° to 90°, and the second angle (A2) ranges from 30° to 70°. In some embodiments, a difference between the first angle (A1) and the second angle (A2) ranges from 30° to 60°.

Next, referring to FIGS. 8 to 10, the second passivation layer 5 exposed

from the first photoresist layer 61 between the gate electrode 4 and the drain electrode 2 is etched to a depth (H) that ranges from 50 nm to 2000 nm so as to form the first groove 63. Referring to FIG. 9, in the gate length direction (x), the first groove 63 has the first sidewall 511 that is closer to the gate electrode 4 than the drain electrode 2, and the second sidewall 512 that is opposite to the first sidewall 511. The first sidewall 511 forms the first inclining angle (A3) with the imaginary line parallel to the gate length direction (x), and the second sidewall 512 and the imaginary line parallel to the gate length direction (x) form the second inclining angle (A4). Both of the first inclining angle (A3) and the second inclining angle (A4) are formed outside the first groove 63.

Referring again to FIGS. 9, 10, and 11, the first photoresist layer 61 is removed, and a second photoresist layer 64 is formed and photolithographically etched to form a second window 65. As shown in FIG. 11, in the gate length direction (x), a dimension (L4) of a bottom portion of the second window 65 ranges from 0.5 μm to 3 μm, and a dimension (L5) of a top portion of the second window 65 ranges from 1 μm to 4 μm.

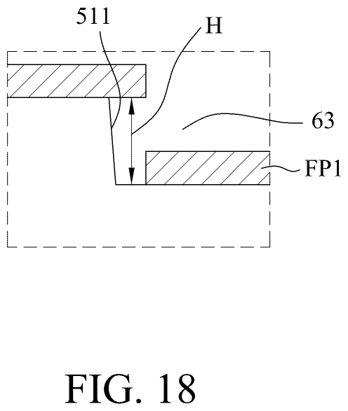

Referring to FIGS. 12 and 13, the field plate structure 8 is formed in the second window 65 by electron beam physical vapor deposition. The field plate structure 8 have two metal layers which are formed as follows. Firstly, a bottom metal layer (not shown in FIGS. 12 and 13) is formed on the second passivation layer 5 and the first groove 63, with a thickness (FP1) that is smaller than the depth (H) of the first groove 63 shown in FIG. 18. After a metal stripping process, a portion of the bottom metal layer in the first groove 63 will have a shape as shown in FIG. 18. Such is due to the first sidewall 511 of the first groove 63 with the first inclining angle (A3), which is close to 90 degrees (see FIG. 10) being relatively steep, so that the bottom metal layer is unable to be formed on the first sidewall 511 due to the collimated film coverage property of the electron beam physical vapor deposition. Therefore, the bottom metal layer does not cover the first side wall 511, but has a metal extension portion formed at an intersection of the first sidewall 511 and the top surface of the second passivation layer 5 due to adsorption property of the metal. When forming a top metal layer (not shown in FIG. 18) on the bottom metal layer, an area under the metal extension portion in the first groove 63 is blocked by the metal extension portion, so the top metal layer is unable to cover the area. As a result, the cavity 66 and the field plate structure 8 are formed, and the cavity 66 is formed in the first groove 63 adjacent to the first sidewall 511 of the first groove 63 closer to the gate electrode 4. The field plate structure 8 further includes the first portion 81, the second portion 82, the third portion 83 that extends downwardly from the first portion 81 to the second portion 82, and the extension portion 84 that is disposed in the first groove 63 of the second passivation layer 5 between the drain electrode 2 and the gate electrode 4. The first portion 81 is disposed on the gate cap 42 of the gate electrode 4. The second portion 82 is disposed between the gate electrode 4 and the drain electrode 2, and extends on the second passivation layer 5 in the gate length direction (x). The source electrode 1, the gate electrode 4, the drain electrode 2, and the field plate structure 8 are spaced apart by the first passivation layer 3 and the second passivation layer 5.

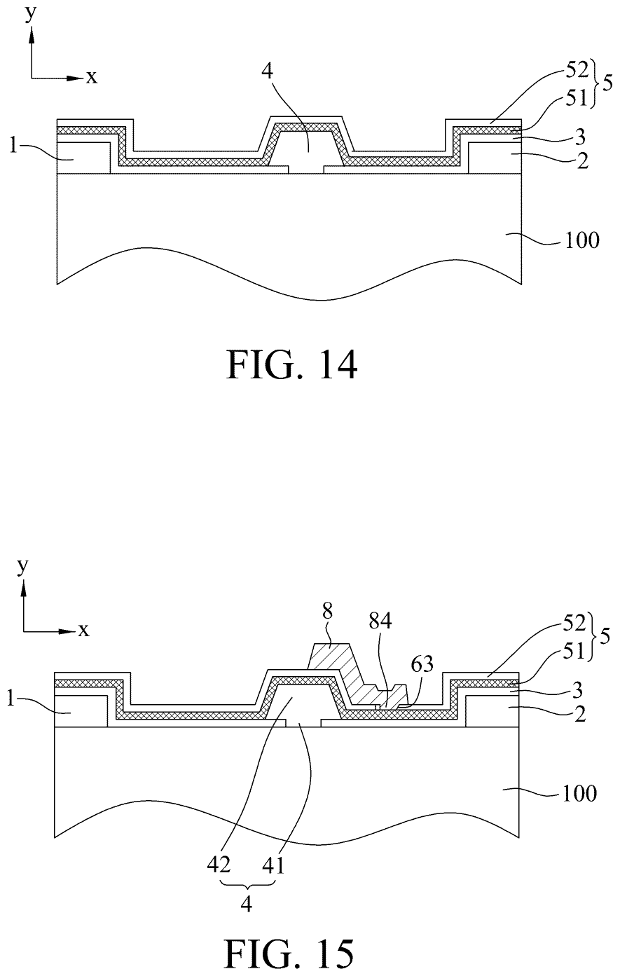

Referring to FIGS. 14 and 15, in a second embodiment of the disclosure, the second passivation layer 5 has two layers one of which is in contact with the first passivation layer 3 and is made of aluminum oxide. The difference between the first embodiment and the second embodiment resides in that the second passivation layer 5 further includes an intermediate layer made of aluminum oxide (Al₂O₃), which is an etch stop layer. In particular, the second passivation layer 5 includes two dielectric layers: a first dielectric layer 51 and a second dielectric layer 52. The first dielectric layer 51 is made of aluminum oxide, and the second dielectric layer 52 and the first passivation layer 3 are made of silicon nitride. By using the first dielectric layer 51 as the intermediate layer, during the forming of the first groove 63 by etching the second dielectric layer 52, a combination of dry etching and wet etching methods may be used for achieving high selectivity ratio and high uniformity. Dry etching is used to etch silicon nitride, and wet etching is used to etch aluminum oxide to avoid problems such as poor uniformness, i.e., unevenness in depth formed by etching, which is encountered by conventional etching methods in which the depth is controlled by controlling etching durations.

As shown in FIG. 15, the first groove 63 is formed in the second dielectric layer 52. The depth of the first groove 63 equals to a thickness of the second dielectric layer 52. Specifically, the second embodiment of the HEMT device according to the disclosure includes the semiconductor epitaxial layer 100 which includes the substrate, the channel layer, and the barrier layer sequentially disposed in the bottom-top direction (y), the source electrode 1, the drain electrode 2, and the gate electrode 4 disposed on the semiconductor epitaxial layer 100. The source electrode 1 and the drain electrode 2 are disposed opposite to each other. The gate electrode 4 has a T shape, is disposed between the source electrode 1 and the drain electrode 2, and includes the gate foot 41 and the gate cap 42. In the bottom-top direction (y), the thickness of the gate cap 42 ranges from 0.1 μm to 1 μm, and the thickness of the gate foot 41 ranges from 0.05 μm to 0.5 μm. In the gate length direction (x), i.e., the direction from the source electrode 1 to the drain electrode 2, the dimension of the gate foot 41 ranges from 0.1 μm to 1 μm. The gate length direction (x) and the bottom-top direction (y) are perpendicular to each other.

In the second embodiment, the HEMT device further includes the field plate structure 8, the first passivation layer 3, and the second passivation layer 5. The first passivation layer 3 is disposed between the gate cap 42 of the gate electrode 4 and the semiconductor epitaxial layer 100. The second passivation layer 5 is disposed between the field plate structure 8 and the gate electrode 4. The second passivation layer 5 includes the first dielectric layer 51 that has a thickness ranging from 5 nm to 50 nm, and the second dielectric layer 52 that has a thickness ranging from 90 nm to 2000 nm. The first dielectric layer 51 is made of Al₂O₃. The second passivation layer 5 covers the gate electrode 4 at the gated region), and covers the first passivation layer 3 at the non-gated region). The field plate structure 8 includes the first portion 81, the second portion 82, and the third portion 83 that extends downwardly from the first portion 81 to the second portion 82. The first portion 81 is disposed on the gate cap 42 of the gate electrode 4. The second portion 82 is disposed between the gate electrode 4 and the drain electrode 2, and extends on the second passivation layer 5 in the gate length direction (x). The source electrode 1, the gate electrode 4, the drain electrode 2, and the field plate structure 8 are spaced apart by the first passivation layer 3 and the second passivation layer 5. The field plate structure 8 further includes the extension portion 84 that is disposed in the first groove 63 of the second passivation layer 5 between the drain electrode 2 and the gate electrode 4. The first groove 63 is formed by penetrating the second dielectric layer 52. During the forming of the extension portion 84 of the field plate structure 8 and the first groove 63 by etching the dielectric materials, the combination of dry etching and wet etching methods is used for achieving high selectivity ratio and high uniformity. Dry etching is used to etch silicon nitride, and wet etching is used to etch aluminum oxide to avoid problems such as poor uniformness (i.e., unevenness in depth) of the first dielectric layer 51 and the second dielectric layer 52, which are encountered by conventional etching methods in which the depth is controlled by controlling etching durations.

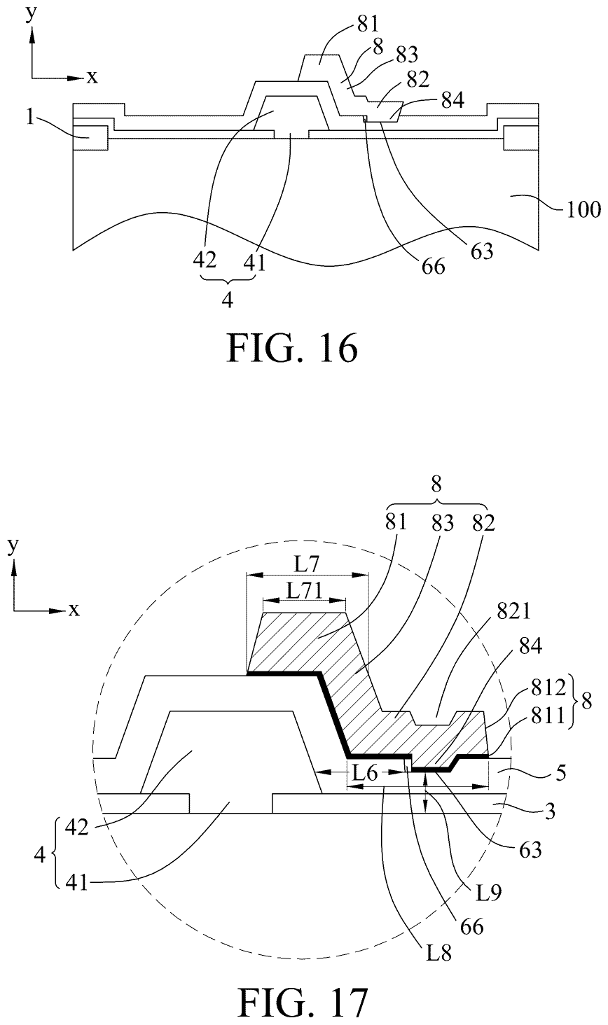

Referring to FIGS. 16 and 17, a third embodiment of the disclosure differs from the first embodiment and the second embodiment in that the second portion 82 does not include the second groove 821 (see FIG. 13). The field plate structure 8 includes the first portion 81, the second portion 82, and the third portion 83 that extends downwardly from the first portion 81 to the second portion 82. The first portion 81 is disposed on the gate cap 42 of the gate electrode 4. The second portion 82 is disposed between the gate electrode 4 and the drain electrode 2, and extends on the second passivation layer 5 in the gate length direction (x). The source electrode 1, the gate electrode 4, the drain electrode 2, and the field plate structure 8 are spaced apart by the first passivation layer 3 and the second passivation layer 5. The field plate structure 8 further includes the extension portion 84 that is disposed in the first groove 63 of the second passivation layer 5 between the drain electrode 2 and the gate electrode 4. The cavity 66 is formed in the first groove 63, and is adjacent to the first sidewall 511 of the first groove 63 that is closer to the gate electrode 4 than the drain electrode 2. The second portion 82 and the extension portion 84 form a Z-shape, thereby enabling a top surface of each of second portion 82 and the extension portion 84 to be flatter, so as to improve the performance of the RF device.

Referring to FIG. 17, a fourth embodiment of the disclosure differs from the previous embodiments in that in the fourth embodiment, the field plate structure 8 includes a bottom metal layer 811 and a top metal layer 812. The top metal layer 812 is a continuous layer, and the bottom metal layer 811 is discontinued at the cavity 66. In this embodiment, the bottom metal layer 811 is made of titanium and has a thickness ranging from 30 nm to 100 nm (e.g., from 50 nm to 60 nm). The bottom metal layer 811 may include metallic materials that may enhance adhesion between layers, such as titanium, nickel, aluminum, chromium, and vanadium. A thickness of the top metal layer 812 ranges from 300 nm to 1000 nm (e.g., from 500 nm to 600 nm). The thickness of the top metal layer 812 is greater than the thickness of the bottom metal layer 811. The top metal layer 812 may have a single layered structure or a multilayered structure, and is mainly made of gold. The top metal layer 812 may also include metallic materials that prevent gold diffusion such as platinum, nickel, molybdenum, palladium, tungsten, and vanadium, and metallic materials that enhance adhesion between layers and provide protection such as metallic titanium, nickel, aluminum, chromium, and vanadium.

Referring to FIG. 18 in combination with FIGS. 16 and 17, the bottom metal layer 811 is first deposited on the second passivation layer 5 with the thickness (FP1) that is smaller than the depth (H) of the first groove 63. After the metal stripping process, the portion of the bottom metal layer 811 in the first groove 63 has a shape as shown in FIG. 18. Due to the steep first sidewall 511 with the first inclining angle (A3) (see FIG. 10) that is close to 90 degrees, the bottom metal layer 811 is unable to be formed on the first sidewall 511 due to a collimated film coverage property of the electron beam physical vapor deposition; therefore, the first sidewall 511 is not covered by metals. The bottom metal layer 811 has the metal extension portion formed at the intersection of the first sidewall 511 and the top surface of the second passivation layer 5 due to adsorption property of the metals. When forming the top metal layer 812 by vapor deposition, the area under the metal extension portion in the first groove 63 is blocked by the metal extension portion, and therefore the area is not covered by the top metal layer 812, thereby forming the cavity 66 and the field plate structure 8.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A high electron mobility transistor (HEMT) device, comprising:
a semiconductor epitaxial layer;
a source electrode, a drain electrode, and a gate electrode disposed on said semiconductor epitaxial layer, said source electrode and said drain electrode being disposed opposite to each other, said gate electrode being disposed between said source electrode and said drain electrode, said gate electrode including a gate foot and a gate cap;
wherein said HEMT device further includes a field plate structure, a first passivation layer, and a second passivation layer, said field plate structure including a first portion, a second portion, and a third portion that extends downwardly from said first portion to said second portion, said first portion being disposed on said gate cap of said gate electrode, said second portion being disposed between said gate electrode and said drain electrode, and extending on said second passivation layer along a gate length direction, said first passivation layer being disposed between said gate cap of said gate electrode and said semiconductor epitaxial layer, said second passivation layer being disposed between said field plate structure and said gate electrode, and having a first groove, said second passivation layer covering said gate electrode at a gated region, and covering said first passivation layer at a non-gated region;
wherein said field plate structure further includes an extension portion that is disposed in said first groove of said second passivation layer between said drain electrode and said gate electrode, said first groove having a first sidewall that is closer to said gate electrode than said drain electrode, and a second sidewall opposite to said first sidewall along said gate length direction, said first sidewall forming a first inclining angle with an imaginary line parallel to said gate length direction, said second sidewall and said imaginary line parallel to said gate length direction forming a second inclining angle, both of said first inclining angle and said second inclining angle being formed outside said first groove, said first inclining angle being greater than said second inclining angle.

2. The HEMT device as claimed in claim 1, wherein a cavity is formed in said first groove, and is surrounded by said second passivation layer and said field plate structure.

3. The HEMT device as claimed in claim 1, wherein said first inclining angle ranges from 80° to 90°.

4. The HEMT device as claimed in claim 1, wherein said second inclining angle ranges from 30° to 70°.

5. The HEMT device as claimed in claim 1, wherein a difference between said first inclining angle and said second inclining angle ranges from 20° to 50°.

6. The HEMT device as claimed in claim 1, wherein said first portion includes a bottom surface contacting said second passivation layer and a top surface opposite to said bottom surface, each of said bottom surface and said top surface having an end portion proximate to said source electrode, a projection of said end portion of said bottom surface on said semiconductor epitaxial layer being closer to said source electrode than a projection of said end portion of said top surface on said semiconductor epitaxial layer.

7. The HEMT device as claimed in claim 6, wherein said gate foot has a gate foot bottom surface, a projection of said bottom surface on said semiconductor epitaxial layer and a projection of said top surface on said semiconductor epitaxial layer overlapping a projection of said gate foot bottom surface of said gate foot on said semiconductor epitaxial layer.

8. The HEMT device as claimed in claim 1, wherein a distance between a bottom surface of said first groove and a top surface of said semiconductor epitaxial layer ranges from 100 nm to 500 nm.

9. The HEMT device as claimed in claim 1, wherein a thickness of said first passivation layer ranges from 50 nm to 500 nm, and a thickness of said second passivation layer ranges from 100 nm to 2000 nm.

10. The HEMT device as claimed in claim 1, wherein said second passivation layer is a single layered structure or a multilayered structure, said first passivation layer being made of a silicon nitride material.

11. The HEMT device as claimed in claim 10, wherein said second passivation layer has two layers, one of which is in contact with said first passivation layer, and is made of an aluminum oxide material.

12. The HEMT device as claimed in claim 1, wherein a dimension of said second portion along said gate length direction ranges from 0.2 μm to 3 μm.

13. The HEMT device as claimed in claim 1, wherein along said gate length direction, a dimension of said second portion is greater than a dimension of said first portion.

14. The HEMT device as claimed in claim 2, wherein along said gate length direction, a dimension of said cavity ranges from 0.01 μm to 0.1 μm.

15. The HEMT device as claimed in claim 2, wherein along said gate length direction, a minimum distance between said cavity and said gate electrode ranges from 0.2 μm to 2 μm.

16. The HEMT device as claimed in claim 2, wherein said field plate structure includes a bottom metal layer and a top metal layer, said top metal layer being a continuous layer, said bottom metal layer being discontinued at said cavity.

17. A method for manufacturing an HEMT device, comprising steps of:
forming a semiconductor epitaxial layer;
forming a source electrode and a drain electrode that are opposite to each other on the semiconductor epitaxial layer;
forming a first passivation layer;
forming a gate electrode;
forming a second passivation layer on the first passivation layer and the gate electrode;
forming and photolithographically etching a first photoresist layer to form a first window that exposes the second passivation layer, followed by a photoresist reflow process under a temperature ranging from 80° C. to 200° C. for a period of 2 minutes to 60 minutes, the first window being located between the gate electrode and the drain electrode and being closer to the gate electrode along a gate length direction, a bottom of the first photoresist layer that is in contact with a surface of the second passivation layer having a first length in the gate length direction from a point on the surface of the second passivation layer closer to the gate electrode at a drain side to a bottom of a first window wall of the first window closer to the gate electrode than the drain electrode, the bottom of the first photoresist layer that is in contact with the second passivation layer further having a second length in the gate length direction from the drain electrode to a bottom of a second window wall of the first window closer to the drain electrode than the gate electrode, the second length being greater than the first length, the first window wall forming a first angle with the second passivation layer proximate to the gate electrode, the second window wall forming a second angle opposite to the first angle and distal from the gate electrode, the second angle being smaller than the first angle, both of the first angle and the second angle being formed outside the first window;
etching the second passivation layer exposed from the first photoresist layer between the gate electrode and the drain electrode to form a first groove;
removing the first photoresist layer, and forming and photolithographic etching a second photoresist layer to form a second window; and
depositing a field plate structure in the second window.

18. The method as claimed in claim 17, wherein a cavity is formed in the first groove and is adjacent to the first sidewall of the first groove that is closer to the gate electrode.

19. The method as claimed in claim 17, wherein a difference between the first angle and the second angle ranges from 20° to 50°.

20. The method as claimed in claim 17, wherein the field plate structure includes a first portion, a second portion, a third portion that extends downwardly from the first portion to the second portion, and an extension portion that is disposed in the first groove of the second passivation layer between the drain electrode and the gate electrode.
